(19) United States
(12) Patent Application Publication
(10) Pub. No.: US 2008/0186753 A1
(43) Pub. Date: Aug. 7, 2008

(54) High density one time programmable memory

(75) Inventors: Myron Buer, Gilbert, AZ (US); Bassem F. Radieddine, Aliso Viejo, CA (US); Douglas D. Smith, Mesa, AZ (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/702,076

(22) Filed: Feb. 5, 2007

(51) Int. Cl. G11C 17/16

(52) U.S. Cl. 365/96

(57) ABSTRACT

A one time programmable memory cell for use in high-density memory devices is provided. The one time programmable memory cell includes a fuse device connected to a bit line and a select device and a select device connected to a row select line and to ground. The fuse device may be a thin oxide transistor having its gate connected to the bit line, its source connected to the select device, and a floating or non-existent. Alternatively, the fuse device may be a thin oxide transistor. The high density memory device includes a plurality of the one time programmable memory cells arranged in an array and adapted to be programmed using a high voltage.

### FIELD OF THE INVENTION

The present invention relates generally to one time programmable memory cells.

### BACKGROUND OF THE INVENTION

Two types of memory devices are commonly used in the field of data storage. The first type is volatile memory in which stored information is lost when power is removed. The second type is non-volatile memory in which the information is preserved after the power is removed. Non-volatile memory may be designed for multiple programming or for one-time programming. Examples of multiple programmable non-volatile memory include electrically erasable programmable read only memories (EEPROMs) and flash memory. Unlike a multiple programmable memory, a one-time programmable non-volatile memory can be programmed only once. The programming typically involves the “blowing” of a fuse element of the cell. The programming of a one-time programmable memory is irreversible.

Many modern applications require the secure storage of large amounts of data in non-volatile memories. For example, as the size and number of cryptographic keys increases for a given application or set of applications, the amount of non-volatile memory cells required to store the information increases. Because of the nature of the information required in these security applications, non-volatile memory storing these keys must be tamper-resistant and prohibitively difficult to read by inspection.

Because of the area required for the fuse element, one-time programmable memory cells have not been practical for high density applications. Instead, electrically erasable programmable read only memories (EEPROMs) have been used in high density applications. An EEPROM can be electrically erased and programmed multiple times. However, this increased flexibility increases the design complexity, area, and cost and decreases the security of the data stored therein. In addition, many applications do not require multiple programming.

Furthermore, the manufacturing techniques used to form such non-volatile memories are quite different from standard logic processes, thereby dramatically increasing the complexity and chip size of such memories. For example, one method for implementing an EEPROM is through the use of a double poly-silicon process. The double poly-silicon process is a special process requiring extra process masks. These special processes increase the expense of the fabrication of multiple programmable non-volatile memories.

What is therefore needed is a low cost, secure one time programmable memory which can be used in high density applications where multiple programming is not required.

What is further needed is a high density memory having reduced area that can be manufactured using standard manufacturing processes.

### BRIEF DESCRIPTION OF THE DRAWINGS

The accompanying drawings, which are incorporated herein and form a part of the specification, illustrate the present invention and, together with the description, further serve to explain the principles of the invention and to enable a person skilled in the pertinent art to make and use the invention.

FIG. 1 depicts a common one-time programmable (OTP) memory cell used in non-volatile memory arrays.

FIG. 2 depicts a high density two transistor OTP memory cell, according to embodiments of the present invention.

FIG. 3 depicts a high density OTP memory cell, according to embodiments of the present invention.

FIG. 4 depicts a high density OTP memory device, according to embodiments of the present invention.

FIG. 5 depicts a flowchart of an exemplary method for programming a single memory cell in a memory cell array, according to embodiments of the present invention.

FIG. 6 depicts a flowchart of an exemplary method for reading a set of memory cells in a memory cell array, according to embodiments of the present invention.

FIG. 7 depicts a flowchart of an exemplary method for verifying the programming for a set of memory cells in a memory cell array, according to embodiments of the present invention.

The present invention will now be described with reference to the accompanying drawings. In the drawings, like reference numbers can indicate identical or functionally similar elements. Additionally, the left-most digit(s) of a reference number may identify the drawing in which the reference number first appears.

### DETAILED DESCRIPTION OF THE INVENTION

### 1. High Density One Time Programmable Memory Cell

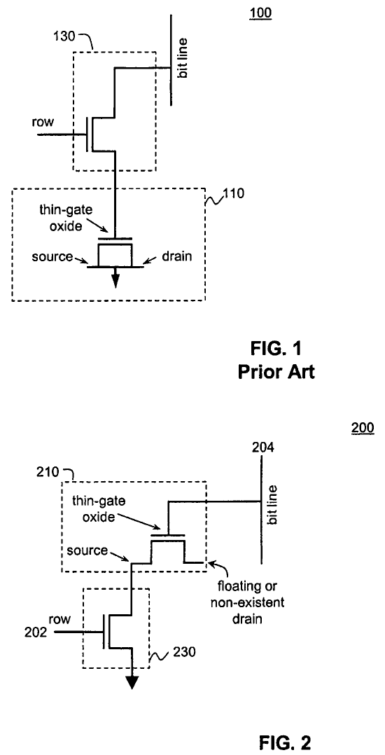

FIG. 1 depicts a common one-time programmable (OTP) memory cell 100 used in non-volatile memory arrays. OTP memory cell 100 includes a fuse element 110 and a select device 130. Fuse element 110 is comprised of a thin gate oxide transistor. Select device 130 is a MOS transistor. As shown in FIG. 1, the gate of fuse element 110 is coupled to the source of select transistor 130. The source and drain of fuse element 110 are connected to ground. This connection of the source and drain of the fuse element to ground requires significant area, limiting the use of OTP 100 in high-density applications.

FIG. 2 depicts a high density two transistor OTP memory cell 200, according to embodiments of the present invention. OTP memory cell 200 includes a fuse element 210 coupled to a select device 230. As can be seen in FIG. 2, unlike prior OTP memory cells in which the select device is coupled to the bit line (such as depicted in FIG. 1), fuse element 210 is coupled to bit line 204. This structure allows a decrease in the area required for memory cell 200 while maintaining the same current for programming the cell 200.

In an embodiment, fuse element 210 is a thin oxide MOS transistor including, but limited to, an NMOS transistor, a PMOS transistor, or an NMOS transistor with native Vₜ implant. Fuse element 210 has its gate coupled to bit line 204 and its source coupled to the drain of select device 230.

The drain of fuse element 210 is left floating or is non-existent. The use of a floating or non-existent drain allows for a reduction in the area of the fuse element. The reduction in size of fuse element allows memory cell 200 to be used in high density applications. Furthermore, the size reduction provides advantages for data security. Because OTP memory cells are often used to store sensitive security information such as cryptographic keys, a smaller fuse size increases the difficulty of reverse engineering the fuse data by visually examining the fuse element.

Select device 230 is any MOS transistor including but not limited to an NMOS transistor and a PMOS transistor. The gate of select device 230 is coupled to row select line 202 and the source of select device 230 is coupled to ground.

To program a memory cell 200, the row select line 202 is raised to a logic high level, causing select device 230 to conduct current. The voltage of bit line 204 is also increased to a high level. Hence, the fuse element 210 sees a high voltage between its gate and source. The voltage is sufficient to break down the thin gate oxide of the fuse (e.g., a voltage in the 3-5V range). When the gate oxide is broken down, a conductive path is formed between the gate and the source/drain regions of the transistor. If the memory cell 200 is to be left unprogrammed, the row select line 202 is held at a logic low level and the voltage of bit line 204 is not taken higher than 3V.

An unprogrammed thin gate oxide fuse device has a high resistance. A programmed thin gate oxide fuse device (commonly referred to as a “blown” fuse) has a low resistance. The state assigned to a programmed fuse may be determined by a specific application or implementation. For example, in an application, a programmed fuse (low resistance) may be assigned to a logic zero state and an unprogrammed fuse (high resistance) may be assigned to a logic one state. Alternatively, a programmed fuse may be assigned to a logic one state and an unprogrammed fuse may be assigned to a logic zero state.

A read operation is used to read a memory cell. During a read operation, the state of bit line 204 determines the value of the data stored in memory cell 200. To read memory cell 200, bit line 204 is set to at a specific voltage level and row select line 202 is taken to a logic high level. Select device 230 then begins conducting current. If fuse device 210 is programmed, a connection is created from bit line 204 to the source of select device 230. Because select device 230 is also conducting, bit line 204 is discharged to a low level (e.g., ground). If fuse device 210 is not programmed, an open circuit exists between bit line 204 and select device 230. Bit line 204 then maintains its voltage level and will be read as unprogrammed.

A verification operation is used to verify that a memory cell has been successfully programmed. During a verification operation, row select line 202 is taken to a logic high level, bit line 204 is set of a specific voltage level, and a current is applied to bit line 204 in a direction opposite fuse element 210. As described above, if fuse device 210 is programmed, a connection is created from bit line 204 to the source of select device 230. If the fuse element 210 has been successfully programmed, the applied current is defeated and the bit line 204 is pulled to a logic low level.

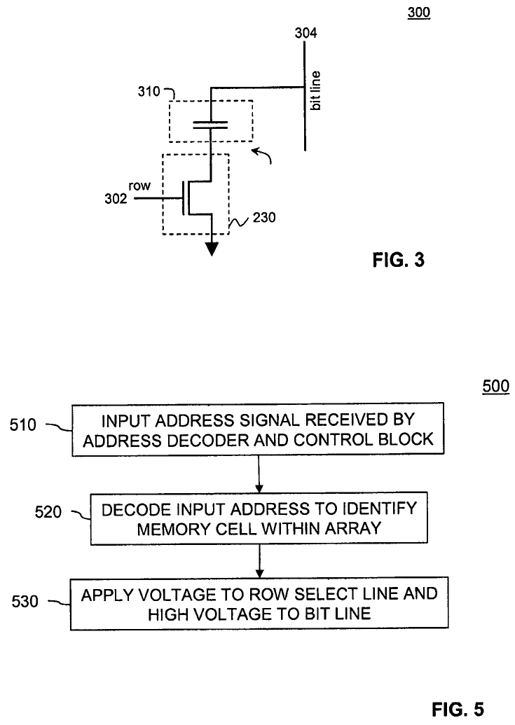

FIG. 3 depicts a high density one transistor-one capacitor OTP memory cell 300, according to embodiments of the present invention. OTP memory cell 300 includes a fuse device 310 coupled to a select device 230. In memory cell 300, fuse device 310 is a thin oxide capacitor such as a thin oxide NMOS capacitor or a thin oxide PMOS capacitor. The first terminal of fuse device 310 is coupled to bit line 304 and the second terminal of fuse device 310 is coupled to the drain of select device 230. The program, read, and verify operations for memory cell 300 are the same as described above for memory cell 200.

### 2. High Density One Time Programmable Memory Device

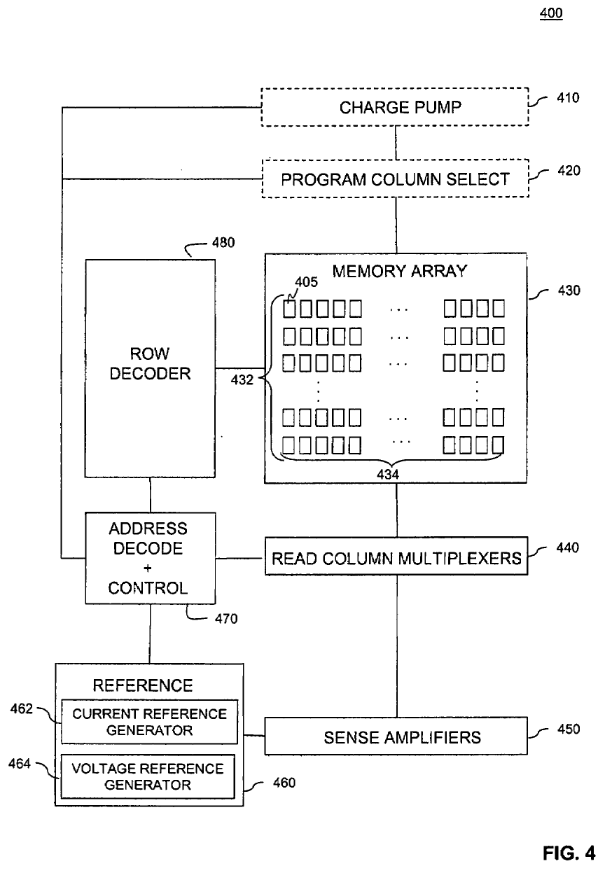

FIG. 4 depicts a high density OTP memory device 400, according to embodiments of the present invention. Memory device 400 includes a memory array 430, an address decoder and control block 470, a row decoder 480, an optional program column select block 420, an optional charge pump 410, optional read column multiplexers 440, reference block 460, and one or more sense amplifiers 450.

Memory array 430 includes a large number of high density OTP memory cells 405. Memory cells 405 may be the two-transistor high density memory cell 200 described above in reference to FIG. 2. Alternatively, memory cells 405 may be the capacitor-transistor high density memory cell 300 described above in reference to FIG. 3. In an embodiment, the OTP memory cells 405 are arranged in a plurality of rows 432 and columns 434 forming an array. In this embodiment, the memory array 430 comprises a total of “n” rows and “m” columns, where m may be greater than, equal to or less than n. A column of memory cells shares a single bit line. In an embodiment, a row 432 shares a common row select line.

Address decoder and control sub-block 470 is configured to control internal signals of memory block 400. Address decoder and control sub-block 470 receives an address or range of addresses and optionally a requested operation (e.g., program, read, or verify). The address or addresses may be received from an external source. The input address signals identify the memory cell or cells to be programmed, read, or verified.

Row decoder 480 is coupled to memory array 430 and address decoder and control block 470. Row decoder 480 is configured to select one row at a time from memory array 430. Row decoder 480 receives a control signal from address decoder and control block 460. The control signal indicates the mode of operation (e.g., program, read, or verify) and the address or range of addresses to be selected. A row is selected by raising its row select line to a voltage high level (e.g., 5V).

Program column select 420 is configured to select one or more bit lines during programming operation. Program column select 420 is optional. Program column select 420 receives a control signal from address decoder and control block. The control signal includes the mode of operation (e.g., program) and the address or range of addresses of the cells to be programmed. Program column select 420 selects a column by raising its bit line to a voltage high level (e.g., 5V). Program column select 420 allows for a single cell or group of cells to be programmed. When not present, all columns are selected during a program operation. By selecting a single column at a time, the size of the charge pump required for the memory block 400 can be reduced.

Charge pump 410 is optional. When present, charge pump 410 generates a high voltage supply (approximately 5V) from a lower core voltage supply (e.g., 1.0V or 2.0V) for programming the memory cells. When not present, the high voltage is provided by an external supply. In an embodiment, charge pump 410 is coupled to one or more bit lines associated with columns in memory array 430 by program column select 420.

Memory block 400 includes one or more sense amplifiers 450. The number of sense amplifiers is dependent upon the implementation of the memory block. The number of sense amplifiers may be equal to or less than the number of columns in memory array 430. At least one sense amplifier 450 is needed to operate the system. In an embodiment, if there are sixteen columns of memory cells present in array 430, there can be a sense amplifier 450 coupled to each of the sixteen columns in array 430. In other words, because there are sixteen sense amplifiers 450, sixteen memory cells in the row can be read at one time.

Column multiplexer 440 is configured to select the bit lines to be coupled to sense amplifiers 450. Column multiplexer 440 is optional when present, column multiplexer 440 couples the bit lines for selected columns to sense amplifiers 450. Column multiplexer 440 allows for variable aspect ratios of the memory block, increasing the ease of floor planning at the chip level and improving performance of the memory block. For example, if memory block 400 has 16 output channels and 16 sense amplifiers 450, memory array 430 could be designed with 32 physical columns multiplexed to the 16 sense amplifiers via column multiplexer 440.

A sense amplifier 450 is coupled to reference block 460 and memory array 430. Each sense amplifier 450 is configured to sense the voltage of a bit line and compare the sensed voltage to a reference voltage provided by voltage reference generator 464. Sense amplifier 450 determines a state (e.g., programmed or unprogrammed) of the activated or enabled memory cell in array 430.

Reference block 460 includes a current reference generator 462 and a voltage reference generator 464. Current reference generator 462 provides a current to memory array 430 during verification mode. Voltage reference generator 464 provides a reference voltage to sense amplifiers 450. The reference voltage is designed to mimic the fuse device resistance.

### 3. System Operation

### 3.1 Program Mode

Program mode is used to program one or more memory cells in memory array 430. As described above in Section 1, the fuse element contained in each identified memory cell is blown or fused. In other words, the state of each selected memory cell changes as a result of programming.

FIG. 5 depicts a flowchart 500 of an exemplary method for programming a single memory cell in a memory cell array, according to embodiments of the present invention. Flowchart 500 is described with continued reference to the exemplary memory block illustrated in FIG. 4. However, flowchart 500 is not limited to that embodiment. Note that the steps of flowchart 500 do not necessarily have to occur in the order shown.

In step 510, address decoder and control block 470 receives an input address signal.

In step 520, the input address signal is decoded to identify a memory cell 405 within array 430. As part of the decoding process, the row containing the memory cell and the column containing the memory cell are identified. In an embodiment, the address is decoded by address decoder and control block 470. In this embodiment, a first signal is transmitted to row decoder 480 indicating the operation to be performed (i.e., program) and the row to be selected. A second signal is also transmitted to program column select 420 indicating the operation to be performed (i.e., program) and the column to be selected. Alternatively, the address decoder and control block 470 may forward the received address to row decoder 480 and program column select 420 which then perform the decoding operations.

In step 530, a voltage (e.g., voltage high level) is applied to row select line of the identified row by row decoder 480 and a high voltage is applied to the bit line of the identified column by program column select 420. During step 530, the voltage to be applied to the bit line may be supplied by charge pump 410 or by an external voltage supply. The row select signal causes all memory cells in the row to be selected and the bit line select signal causes all memory cells connected to that bit line to be selected. Therefore, only one memory cell has both its row and bit line selected together.

### 3.2 Read Mode

Read mode is used to read the content of a set of memory cells in a memory array. This operation is typically, but not necessarily exclusively, performed after the OTP element memory core 405 has been programmed and verified.

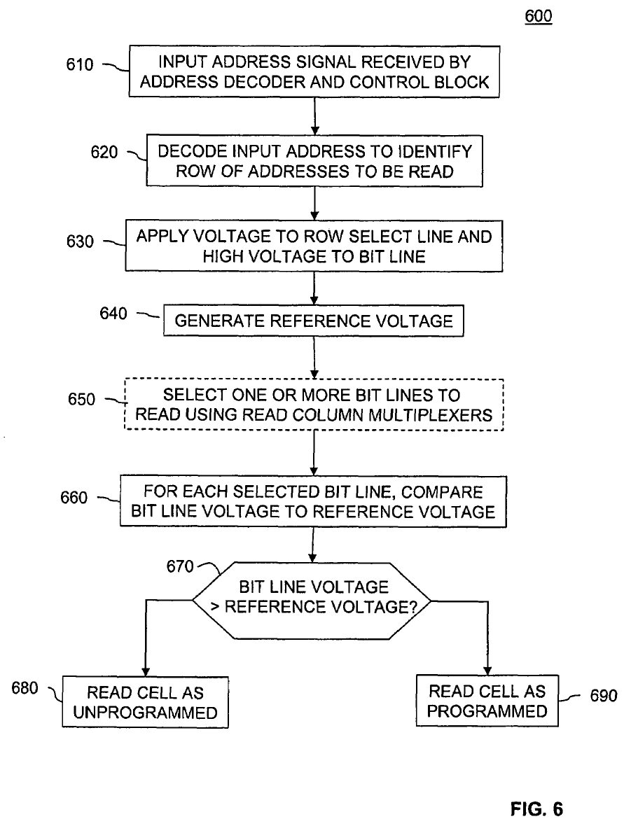

FIG. 6 depicts a flowchart 600 of an exemplary method for reading a set of memory cells in a memory cell array, according to embodiments of the present invention. Flowchart 600 is described with continued reference to the exemplary memory block illustrated in FIG. 4. However, flowchart 600 is not limited to that embodiment. Note that the steps of flowchart 600 do not necessarily have to occur in the order shown.

In step 610, address decoder and control block 470 receives an input address signal indicating a range of addresses to be read.

In step 620, the input address signal is decoded to identify a row containing the range of addresses to be read. In an embodiment, the address is decoded by address decoder and control block 470. In this embodiment, a signal is transmitted to row decoder 480 indicating the operation to be performed (i.e., read) and the row to be selected. Alternatively, the address decoder and control block 470 may forward the received address to row decoder 480 which then performs the decoding operations.

In step 630, a voltage (e.g., voltage high level) is applied to the row select line of the identified row by row decoder 480 and a high voltage is applied to the bit line of each column.

In step 640, a reference voltage is generated by voltage reference generator 464. The reference voltage is supplied to sense amplifiers 450.

In step 650, one or more bit lines to be read are selected using read column multiplexers 440. Step 650 is optional. When present, a subset of the total number of bit lines in the array can be coupled to sense amplifiers 450. When not present, each bit line is coupled to a corresponding sense amplifier 450.

In step 660, for each selected bit line, the bit line voltage is compared to the reference voltage by a sense amplifier 450.

In step 670, a determination is made whether the bit line voltage is greater than the reference voltage. If the bit line voltage is greater than the reference voltage, operation proceeds to step 680. If the bit line voltage is not greater than the reference voltage, operation proceeds to step 690.

In step 680, if the bit line voltage is greater than the reference voltage, then selected memory cell 405 is read as unprogrammed and the corresponding data value is output.

In step 690, if the fuse voltage is less than the threshold voltage, then selected memory cell is read as programmed and the corresponding data value is output.

Note that steps 660-690 may occur in parallel or substantially in parallel for each bit line.

### 3.3 Verify Mode

Verify mode is used to verify that a set of memory cells in a memory array has been programmed successfully. In an embodiment, a verify operation is automatically initiated following a program operation. In addition or alternatively, a verify operation may be initiated via receipt of a command from an external source. Verify mode is essentially the same as read mode except that the reference fuse resistance is smaller in order to compensate for variations in voltage and temperature conditions.

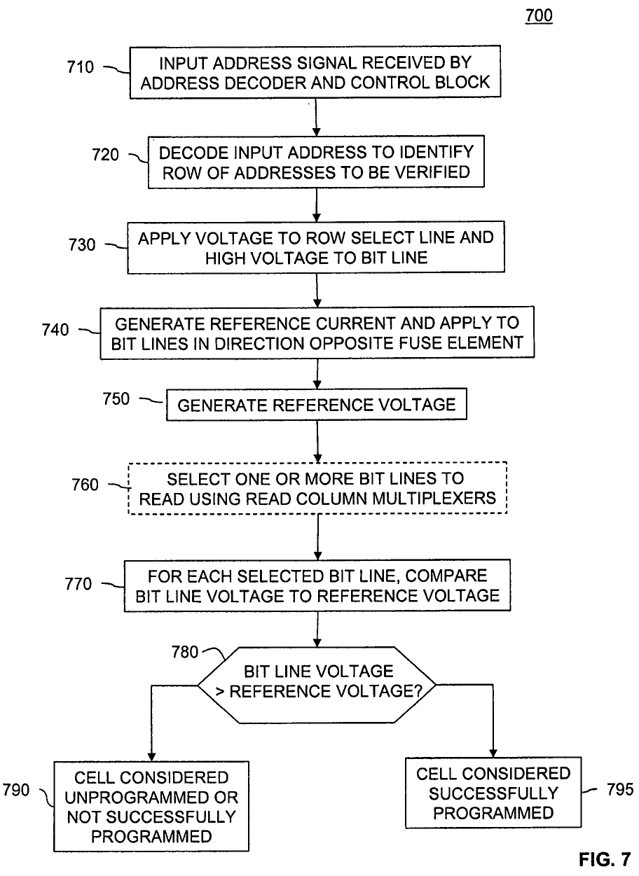

FIG. 7 depicts a flowchart 700 of an exemplary method for verifying the programming for a set of memory cells in a memory cell array, according to embodiments of the present invention. Flowchart 700 is described with continued reference to the exemplary memory block illustrated in FIG. 4. However, flowchart 700 is not limited to that embodiment. Note that the steps of flowchart 700 do not necessarily have to occur in the order shown.

In step 710, address decoder and control block 470 receives an input address signal indicating a range of addresses to be verified.

In step 720, the input address signal is decoded to identify a row of addresses to be verified. In an embodiment, the address is decoded by address decoder and control block 470. In this embodiment, a signal is transmitted to row decoder 480 indicating the operation to be performed (i.e., read) and the row to be selected. Alternatively, the address decoder and control block 470 may forward the received address to row decoder 480 which then performs the decoding operations.

In step 730, a voltage (e.g., voltage high level) is applied to the row select line of the identified row by row decoder 480 and a high voltage is applied to the bit line of each column.

In step 740, a reference current is generated by current reference generator 462 and applied to bit lines in a direction opposite the fuse element of the memory cell.

In step 750, a reference voltage is generated by voltage reference generator 464. The reference voltage is supplied to sense amplifiers 450.

In step 760, one or more bit lines to be verified are selected using read column multiplexers 440. Step 760 is optional. When present, a subset of the total number of bit lines in the array can be coupled to sense amplifiers 450. When not present, each bit line is coupled to a corresponding sense amplifier 450.

In step 770, for each selected bit line, the bit line voltage is compared to the reference voltage by a sense amplifier 450.

In step 780, a determination is made whether the bit line voltage is greater than the reference voltage. If the bit line voltage is greater than the reference voltage, operation proceeds to step 790. If the bit line voltage is not greater than the reference voltage, operation proceeds to step 795.

In step 790, if the bit line voltage is greater than the reference voltage, then selected memory cell 405 is considered unprogrammed or not successfully programmed.

In step 795, if the fuse voltage is less than the reference voltage, then selected memory cell is considered to have been successfully programmed.

Note that steps 770-795 may occur in parallel or substantially in parallel for each bit line.

### 4. Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A one-time programmable memory cell, comprising:
a fuse device connected to a bit line; and
a select device connected to the fuse device and to a select line, a first voltage potential, and the fuse device.

2. The one-time programmable memory cell of claim 1, wherein the fuse device is a thin-oxide MOS transistor.

3. The one-time programmable memory cell of claim 2, wherein a gate of the thin-oxide MOS transistor is connected to the bit line, a source of the thin-oxide MOS transistor is connected to the select device, and a drain of the thin-oxide MOS transistor is floating.

4. The one-time programmable memory cell of claim 2, wherein a gate of the thin-oxide MOS transistor is connected to the bit line, a source of the thin-oxide MOS transistor is connected to the select device, and a drain of the thin-oxide MOS transistor is non-existent.

5. The one-time programmable memory cell of claim 2, wherein the thin-oxide MOS transistor is an NMOS transistor.

6. The one-time programmable memory cell of claim 2, wherein the thin-oxide MOS transistor is an NMOS transistor with a native VT implant.

7. The one-time programmable memory cell of claim 2, wherein the thin-oxide MOS transistor is a PMOS transistor.

8. The one-time programmable memory cell of claim 1, wherein the fuse device is a thin-oxide capacitor.

9. The one-time programmable memory cell of claim 8, wherein a first terminal of the capacitor is connected to the bit line and a second terminal of the capacitor is connected to the select device.

10. The one-time programmable memory cell of claim 1, wherein the select device is a transistor.

11. The one-time programmable memory cell of claim 10, wherein a gate of the select device is coupled to the select line, a source of the select device is coupled to the first voltage potential, and a drain of the select device is connected to the fuse device.

12. The one-time programmable memory cell of claim 1, wherein the first voltage potential is ground.

13. A high-density one-time programmable memory device, comprising:
a plurality of one-time programmable memory cells arranged in a memory array, wherein a one-time programmable memory cell includes:
a fuse device connected to a bit line and to a select device; and
a select device connected to a select line, a first voltage potential, and the fuse device.

14. The high-density one-time programmable memory device of claim 13, wherein the fuse device of the one-time programmable memory cell is a thin-oxide MOS transistor and wherein a gate of the thin-oxide MOS transistor is connected to the bit line, a source of the thin-oxide MOS transistor is connected to the select device, and a drain of the thin-oxide MOS transistor is floating.

15. The high-density one-time programmable memory device of claim 13, wherein the fuse device of the one-time programmable memory cell is a thin-oxide MOS transistor and wherein a gate of the thin-oxide MOS transistor is connected to the bit line, a source of the thin-oxide MOS transistor is connected to the select device, and a drain of the thin-oxide MOS transistor is non-existent.

16. The high-density one-time programmable memory device of claim 13, wherein the fuse device of the one-time programmable memory cell is a thin-oxide capacitor and wherein a first terminal of the capacitor is connected to the bit line and a second terminal of the capacitor is connected to the select device.

17. The high-density one-time programmable memory device of claim 13, wherein the plurality of memory cells are arranged in a plurality of rows and a plurality of columns, wherein a plurality of memory cells in a column share a common bit line and a plurality of memory cells in a row share a common select line.

18. The high-density one-time programmable memory device of claim 17, further comprising:
a device configured to select a column of memory cells and to couple a high voltage to a bit line for the selected column when a memory cell in the column is to be programmed.

19. The high-density one-time programmable memory device of claim 17, further comprising:
a plurality of sense amplifiers; and
a read column multiplexer device configured to couple a set of columns to the plurality of sense amplifiers when a read operation is to be performed.

20. The high-density one-time programmable memory device of claim 13, further comprising:
a charge pump configured to provide a high voltage during a program operation.
